(19) United States
(12) Patent Application Publication
(10) Pub. No.: US 2015/0212163 A1
(43) Pub. Date: Jul. 30, 2015

(54) DEVICE FOR DETECTING REMAINING BATTERY CAPACITY, BATTERY SYSTEM, METHOD OF DETECTING REMAINING BATTERY CAPACITY AND PROGRAM

(71) Applicant: NEC Corporation, Tokyo (JP)

(72) Inventor: Youjirou Nomura, Tokyo (JP)

(21) Appl. No.: 14/425,647

(22) PCT Filed: Sep. 3, 2013
(86) PCT No.: PCT/JP2013/073701

§ 371 Date: Mar. 4, 2015

(30) Foreign Application Priority Data
Sep. 5, 2012 (JP) 2012-195069

(51) Int. Cl. G01R 31/36

(52) U.S. Cl. CPC G01R 31/3648; G01R 31/3606

(57) ABSTRACT

A device for detecting remaining battery capacity (10) includes a voltage detection unit (15), a current detection unit (13) and a control unit (17), wherein the control unit (17) is configured (a) detect actual voltage of the storage battery at start of charging storage battery, (b) obtain power storage amount corresponding to the actual voltage by using a look-up table representing a relationship between voltages and power storage amounts corresponding thereto, (c) calculate power storage amount in the storage battery charged by implemented charging (hereinafter referred to as “calculated power storage amount”), and (d) calculate total power storage amount of the charged storage battery, by adding the calculated power storage amount and the power storage amount at start.

### TECHNICAL FIELD

The present invention relates to a device for detecting remaining battery capacity, a battery system including the same, a method of detecting remaining battery capacity and a program for executing the same. The present invention relates particularly to a device for detecting remaining battery capacity, a battery system including the same, a method of detecting remaining battery capacity and a program for executing the same which allow total power storage amount of storage battery to be detected even when charging is started with certain power storage amount remaining.

### BACKGROUND ART

Conventionally, a battery pack has been known in which a plurality of storage batteries, for example lithium ion secondary batteries, are connected to one another. As a method of detecting a power storage amount of such storage batteries, for example, Patent Document 1 discloses that values of current inputted/outputted in/from storage batteries are measured, the values of current are integrated to thereby calculate actual remaining capacity.

### PRIOR ART REFERENCE

Patent Document 1: Japanese Patent Laid-Open No. 63-208733

### SUMMARY OF INVENTION

### Technical Problem

In such a system in which current value is simply measured as disclosed in Patent Document 1, there is a problem that accumulation of measurement errors in values of current causes a large error in calculated value from actual remaining capacity. To correct the error, it is necessary to pass through a discharge end point and a full charge point as measurement reference points, however, such a system is not practical for typical use of battery.

The object of the present invention is thus to provide a device for detecting remaining battery capacity, a battery system including the same, a method of detecting remaining battery capacity and a program for executing the same which allow total power storage amount of storage battery to be detected even when charging is started with certain power storage amount remaining.

### Solution to Problem

In order to achieve the above-mentioned object, a device for detecting remaining battery capacity according to an embodiment of the present invention includes:

a voltage detection unit configured to detect voltage of a storage battery;

a current detection unit configured to detect current for charging during charging the storage battery; and

a control unit for computing,

the control unit is configured to

(a) detect actual voltage of the storage battery at start of charging storage battery,

(b) obtain power storage amount corresponding to the actual voltage (hereinafter referred to as “power storage amount at start”) by using a look-up table representing a relationship between voltages and power storage amounts corresponding thereto,

(c) calculate power storage amount in the storage battery charged by implemented charging (hereinafter referred to as “calculated power storage amount”), and

(d) calculate total power storage amount of the charged storage battery, by adding the calculated power storage amount and the power storage amount at start.

### Description of Terms

“Device for detecting remaining battery capacity” includes both a device in which a voltage detection unit, a current detection unit and a control unit are disposed in one place, for example disposed in housing, and a device in which they are disposed separately and connected to one another.

“Control unit” may be a computer unit with for example a CPU (Central Processing Unit) for computing, a memory, an interface, which can provide various functions by executing a computer program stored in the memory. So-called one-chip microcomputer can be used in which hardware such as a CPU, a ROM, a RAM, an I/F and a program are provided. Alternatively, the control unit may be one provided as an electric circuit.

“Connection”: when it is said, for example, that an element is connected to another element in the specification, this means both an embodiment in which the both are connected directly to each other and an embodiment in which the both are connected indirectly to each other via one or more intermediate elements. Both wired connection and wireless connection can be used for connection between elements for transmitting electric signals or performing any data communication to each other.

### Advantage of the Invention

The present invention can provided a device for detecting remaining battery capacity and the like which allow total power storage amount of a storage battery to be detected even when charging is started with certain power storage amount remaining.

### BRIEF DESCRIPTION OF THE DRAWINGS

FIG. 1 is a block diagram illustrating a configuration of a battery system according to an embodiment of the present invention.

FIG. 2 is a diagram illustrating one example of a look-up table.

FIG. 3 is a diagram for explaining charging operation and calculation of a total power storage amount of a battery cell in the case where a voltage of the battery cell in starting the charging is, for example, 3.75 V.

FIG. 4 is a flowchart of one example of operations of the battery system.

FIG. 5 is a diagram for explaining operations in the case where recharging is performed after discharge only for a short time after constant-voltage charging and another case.

### DESCRIPTION OF EMBODIMENTS

Embodiments of the present invention are described with reference to the drawings. It is noted that configurations, functions, operations and the like described below are just according to embodiment of the present invention and are not intended to limit the present invention.

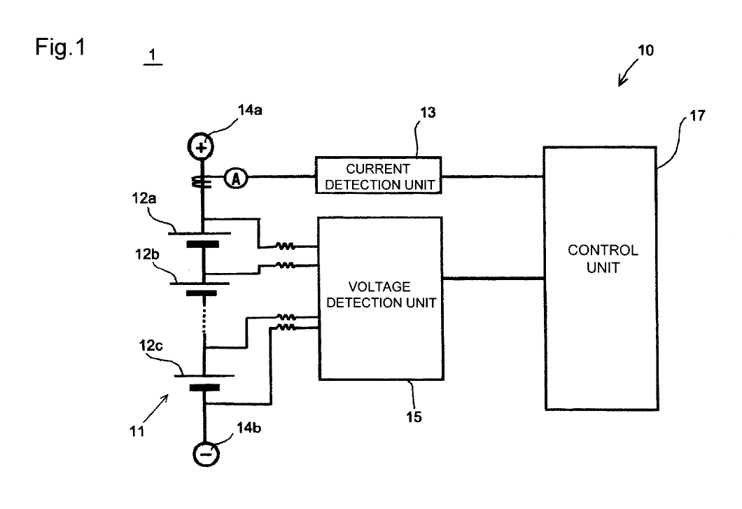

As illustrated in FIG. 1, a battery system 1 includes a device for detecting remaining battery capacity 10 and a battery unit 11, and the device for detecting remaining battery capacity 10 has a current detection unit 13, a voltage detection unit 15 and a control unit 17.

The battery unit 11 has a plurality of battery cells 12a to 12c (each of which is also referred to simply as “battery cell 12”). The battery cells 12 are lithium ion batteries by way of example and are connected in series. It is noted that the number of the battery cells 12 is not limited specific value. One battery cell 12 may be provided instead of limiting to be plural. Other secondary batteries such as nickel-cadmium batteries and nickel-metal hydride batteries other than lithium ion batteries can be used as battery cells 12.

It is noted that the device for detecting remaining battery capacity 10 may have an enclosure for housing at least one of or all of the current detection unit 13, the voltage detection unit 15, and the control unit 17, for example.

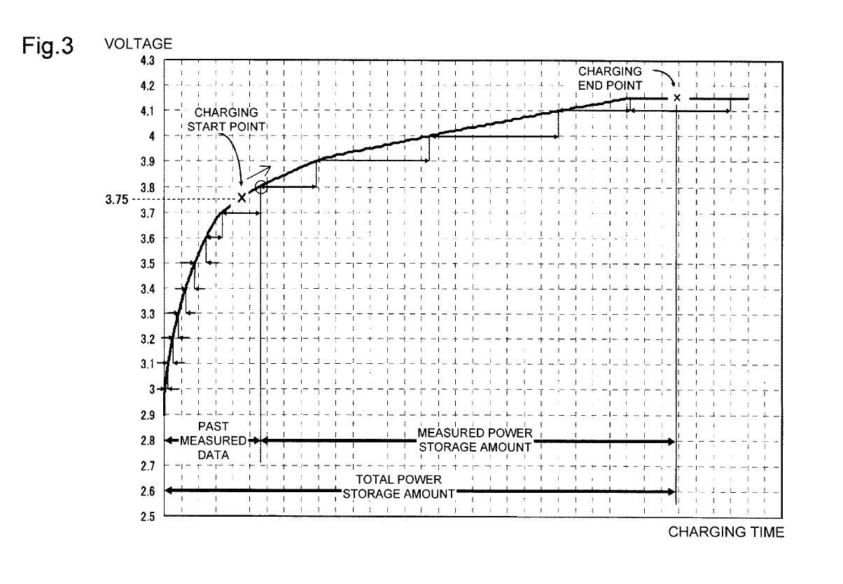

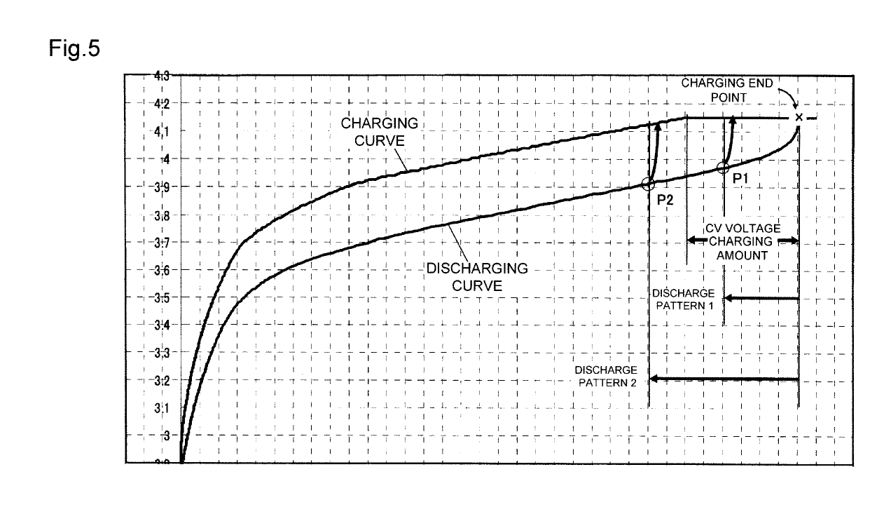

The embodiment is described by way of example with battery cells 12 which show charging curve and discharging curve as illustrated in FIGS. 3 and 5, where the discharge end voltage of the battery cell is approximately 3.0 V.

As illustrated in FIG. 1, terminals 14a and 14b are provided in the battery unit 11 and the battery unit 11 can be charged by connecting a charging device, not shown, to the terminals 14a and 14b. Any conventional charging device (not shown) can be used. With respect to charging method, constant-current/constant-voltage method is used, for example, for lithium ion batteries. In the examples of FIGS. 3 and 5, constant-current charging is performed until voltage of the battery cell 12 reaches approximately 4.15 V, while constant-voltage charging is performed after the voltage reaches approximately 4.15 V.

The current detection unit 13 is configured to detect current inputted/outputted in/from the battery cells 12. The voltage detection unit 15 is configured to detect voltages of the battery cells 12a to 12c.

The control unit 17 is connected to the current detection unit 13 and the voltage detection unit 15. The control unit 17 performs (i) controlling operations of the detection units 13 and 15, and (ii) various computing by using detected values from the detection units 13 and 15. The control unit 17 may be configured to implement the above operations with a program, and moreover, to perform various processes as mentioned later with the program.

Although illustration is omitted in FIG. 1, the battery system 1 may include a storage unit for storing the above-mentioned program. In the storage unit, of course, various data such as a look-up table mentioned later may be stored in addition to the program. The storage unit may be a memory (not-shown) in the computer unit, for example. Alternatively, an external storage device connectable to the computer unit can store data such as the look-up table.

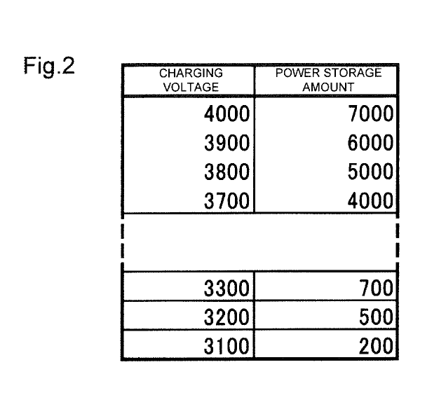

FIG. 2 illustrates an example of the look-up table. Use of the look-up table is described below. “Charging voltage” in a left column of the table refers to voltage of storage battery divided into a plurality of sections. In this example, voltage from 3100 mV to 4000 mV is divided every 100 mV. Of course, not limited to 100 mV, the division may be made, for example, by a smaller value or a larger value.

“Power storage amount” in a right column of the table refers to power storage amount of a battery cell, each amount corresponds to each charging voltage. Numerical values of the “power storage amount” would vary under influence of aging degradation of the battery cell. Preferably, data in the look-up table is updated properly to calculate power storage amount more accurately. Data updating will also be described later.

The look-up table allows power storage amount of battery cell 12 at start of charge to be estimated, for example: a power storage amount is 200 Ah when a detected voltage of the battery cell 12 is 3.1 V (3100 mV), whereas the amount is 5000 Ah at 3.8 V (3800 mV). If voltage of the battery cell 12 is 3.75 V (3750 mV) for example, 5000 Ah is estimated when the voltage reaches 3800 mV after charging is performed.

It is noted that the control unit 17 also performs measuring a power storage amount consumed from the state of full charging (used power storage amount) on the basis of the detection value from the current detection unit 13, and then calculating a remaining battery capacity, after usage, on the basis of a total power storage amount at full charge and a measured used power storage amount.

Next, charging operation of the battery cell by the battery system 1 according to the embodiment is described.

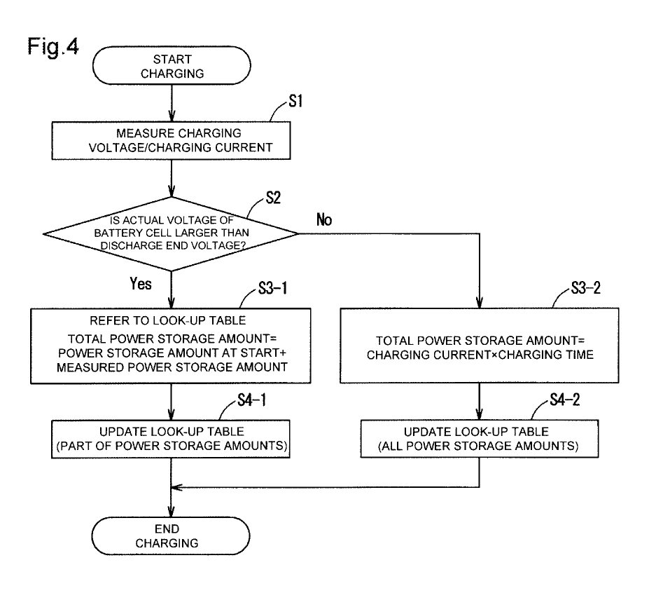

FIG. 3 is a diagram for explaining charging operation and calculation of the total power storage amount of the battery cell in the case where a voltage of battery cell 12 at the start of charging is 3.75 V. In the figure, the horizontal axis of the graph is a charging time and the vertical axis thereof is a voltage [V] of the battery cell. FIG. 4 is a flowchart by way of example illustrating operation of the battery system.

First of all, the charging device (not shown) is connected to the battery unit 11 to start charging, followed by detecting charging current with the current detection unit 13 in step S1. The voltage detection unit 15 detects voltage of the battery cell 12. Timing for starting and/or ending of these detections and the like is not limited to a specific timing but may be arbitrary one. As a system for performing each detection, a conventionally known methods can be properly used.

In step S2, it is determined whether the actual voltage of battery cell 12 is substantially larger than a discharge end voltage (3.0 V in this example). For example, when voltage of the voltage cell 12 is less than 3000 mV, total power storage amount of the battery cell is calculated on the basis of charging current and charging time (step S3-2) after determining that charging has been performed up to the discharge end value and the voltage has reached discharge end voltage. It is noted that determination as above may be automatically performed by the control unit 17, for example.

On the other hand, in step S2 when it is determined that voltage of the battery cell is substantially larger than the discharge end voltage (in other words, in case that charging is started except from the discharge end voltage), remaining battery capacity detection of step S3-1 is performed. As a specific example, assume that voltage of the battery cell 12 is 3.75 V (3750 mV) as illustrated in FIG. 3. In this case, the actual power storage amount of the battery cell 12 can be obtained with the look-up table in FIG. 2. Since the voltage of the battery cell is 3750 mV, charging will be continued till being 3800 mV and the power storage amount of 5000 Ah corresponding to 3800 mV in the look-up table is estimated as the actual power storage amount of the battery cell (this is referred to as “power storage amount at start”). It is noted that the process as above is one example and may be automatically performed by the control unit 17. Similarly, various processes described below can also be automatically performed by the control unit 17.

Power storage amount is calculated by multiplying charging current and charging time (this is referred to as “measured power storage amount”) after the voltage exceeds 3800 mV till discharge end. Total power storage amount is then calculated by adding the “power storage amount at start” and the measured power storage amount.

According to such a calculation of the power storage amount, total power storage amount of the battery cell after charging can be obtained more accurately even when charging is performed except from the discharge end voltage, since the power storage amount remaining in the battery cell 12 is obtained with reference to the look-up table and the power storage amount stored in the actual charging is added thereto to calculate the total power storage amount of the battery cell 12.

Next, updating data of the look-up table is described. When charging from a discharge end voltage (step S4-2) is started, relationship between each voltage and corresponding power storage amount during constant-current charging point is monitored. Specifically, relationship between each voltage and power storage amount at that time point is measured, for example, the power storage amount at the time of reaching 3100 mV being a1 [Ah], the power storage amount at the time of reaching 3200 mV being a2 [Ah], . . . , the power storage amount at the time of reaching 3900 mV being a9 [Ah], and the power storage amount at the time of reaching 3100 mV being a10 [Ah]. Then, by using such monitored data, data of power storage amounts in the look-up table (FIG. 2) are updated.

It is noted that updating may be performed during charging or after charging. For the data update, the control unit 17 may be configured to automatically update data in the look-up table using information such as the power storage amounts a1 and a2 to a9 as above.

On the other hand, when charging is started except from the discharge end voltage (step S4-1), updating is performed only for part of the “power storage amounts” in the look-up data as mentioned below. As a specific example, similarly to the above, a case is supposed where the voltage of the battery cell 12 is 3750 mV. In this case, power storage amounts corresponding to the battery sections of 3900 mV and 4000 mV are newly calculated respectively, and data of the “power storage amounts” in the look-up table are to be updated.

While method for calculating values of “power storage amounts” to be updated is not limited specific one, but any method can be used, for example, it may be one described below:

e1: obtaining power storage amount at start corresponding to the actual voltage of the storage battery from the look-up table (5000 Ah in the case of 3750 mV, 5000 Ah corresponding to 3800 mV after charging);

e2: calculating power storage amount stored by charging during one voltage section (for example, from 3800 mV to 3900 mV), for example, by multiplying the charging current by the charging time;

e3: adding the power storage amount in e2 as above and the power storage amount at start and calculate total power storage amount at the voltage (3900 mV) (for example, 5950 Ah); and

e4: storing the total power storage amount as power storage amount at the voltage (3900 mV) in the table.

Updating data of the “power storage amounts” in look-up table in response to actual condition of the battery cell allows remaining capacity to be detected more accurately in consideration of the situation of degradation of battery cell, since the look-up table is to be prepared in accordance with the condition of the cell, even if performance of the battery vary under influence of aging degradation of battery cell.

(Case where Recharging is Performed After Discharge Only for Short Time After Constant-Voltage Charging)

Battery system 1 according to the embodiment may perform operations below in consideration of charging performed for lithium ion batteries by constant-current/constant-voltage method:

the control unit 17 is configured to (i) determine whether battery cell 12 is in a state where power storage amount stored by the constant-voltage charging has been discharged, when the charging of the battery cell 12 is performed; and to (ii) perform remaining battery capacity detection using the look-up table and/or updating of the look-up table as mentioned above only when state of having been discharged is determined.

For example, voltage become constant (approximately 4.15 V in this example) in constant-voltage charging as illustrated in FIG. 5. Assuming that previous constant-voltage charging is ended at the position of the sign “x” in the figure, in the case where following charging is started from a position where all of power storage amount stored by the constant-voltage charging has not been discharged completely (for example, the position of P1), remaining battery capacity detection using look-up table or updating of the look-up table as mentioned above is not needed, because the following charging is to be the constant-voltage charging from the beginning, the voltage thus keeps constant.

On the other hand, in the case where following charging is started from a position where all of the power storage amount stored by the constant-voltage charging has been discharged completely (for example, the position of P2), the following charging is to be the constant-current charging, and therefore, the remaining battery capacity detection using the look-up table and the data update of the look-up table as mentioned above are performed. By doing so, the advantageous effects similar to the above can be obtained.

While the embodiments of the present invention have been described as above, the present invention is not limited to the contents of the above disclosure but can be modified in various manners.

Incidentally, other than the inventions according to the battery system and the device for detecting remaining battery capacity, the following invention is disclosed in the description:

a method of detecting remaining battery capacity, comprising:

(a) detecting actual voltage of a storage battery with voltage detection means at start of charging storage battery;

(b) obtaining power storage amount corresponding to the actual voltage (hereinafter referred to as “power storage amount at start”) by using a look-up table representing a relationship between voltages and power storage amounts corresponding thereto;

(c) calculating power storage amount in the storage battery charged by implemented charging (hereinafter referred to as “calculated power storage amount”); and

(d) calculating total power storage amount of the charged storage battery, by adding the calculated power storage amount and the power storage amount at start.

For example, in the case where the remaining battery capacity detection as above is performed by a device, the present invention can also be expressed as follows:

a method of detecting remaining battery capacity, performed by one or more computers, including:

obtaining, by the computer, power storage amount corresponding to the detected actual voltage of a storage battery (hereinafter referred to as “power storage amount at start”) by using a look-up table representing a relationship between the voltage and the power storage amount corresponding thereto;

calculating, by the computer, power storage amount in the storage battery charged by implemented charging (hereinafter referred to as “calculated power storage amount”); and

calculating, by the computer, total power storage amount of the storage battery by adding the calculated power storage amount and the power storage amount at start.

There is provided a program causing a computer (which may be one or more computers) to execute the processes of;

(a) referring to a actual voltage of a storage battery, at start of charging storage battery, detected by voltage detection means ;

(b) obtaining power storage amount corresponding to the actual voltage (hereinafter referred to as “power storage amount at start”) by using a look-up table representing a relationship between the voltages and the power storage amounts corresponding thereto;

(c) calculating power storage amount stored in the storage battery charged by implemented charging (hereinafter referred to as “calculated power storage amount”); and

(d) calculating total power storage amount of the charged storage battery, by adding the calculated power storage amount and the power storage amount at start.

The present application discloses a method, a program, and a medium that stores the program, which correspond to the invention of the above-described device, other than the inventions according to the methods and program.

### DESCRIPTION OF THE REFERENCE NUMERALS

1 BATTERY SYSTEM
10 DEVICE FOR DETECTING REMAINING BATTERY CAPACITY
11 BATTERY UNIT
12A-12B AND 12 BATTERY CELLS
13 CURRENT DETECTION UNIT
15 VOLTAGE DETECTION UNIT
17 CONTROL UNIT

1. A device for detecting remaining battery capacity, comprising:
a voltage detection unit configured to detect voltage of a storage battery;
a current detection unit configured to detect current for charging during charging the storage battery; and
a control unit for computing,
the control unit is configured to
(a) detect actual voltage of the storage battery at start of charging storage battery,
(b) obtain power storage amount corresponding to the actual voltage (hereinafter referred to as “power storage amount at start”) by using a look-up table representing a relationship between voltages and power storage amounts corresponding thereto,
(c) calculate power storage amount in the storage battery charged by implemented charging (hereinafter referred to as “calculated power storage amount”), and
(d) calculate total power storage amount of the charged storage battery, by adding the calculated power storage amount and the power storage amount at start.

2. The device for detecting remaining battery capacity according to claim 1, further comprising a storage unit configured to store at least the look-up table.

3. The device for detecting remaining battery capacity according to claim 1, the control unit is further configured to
(e) monitor relationship between voltage and power storage amount during charging, and update power storage amount in the look-up table on the basis of the monitored data.

4. The device for detecting remaining battery capacity according to claim 3, when charge of storage battery is started except from a discharge end, the controller unit is further configured to, in said (e),
(e1) obtain from the look-up table the power storage amount at start corresponding to the actual voltage of the storage battery,
(e2) calculate power storage amount stored by the charging during one voltage section in the look-up table,
(e3) calculate total power storage amount, at the voltage, by adding the power storage amount at start and the power storage amount in said (e2), and
(e4) update the power storage amount corresponding to the voltage with the calculated total power storage amount.

5. The device for detecting remaining battery capacity according to claim 1, wherein the control unit is further configured to
(f) measure used power storage amount of the storage battery, and calculate remaining capacity of power storage amount after usage, by using the total power storage amount after charge and the used power storage amount.

6. The device for detecting remaining battery capacity according to claim 1, wherein the storage battery is a lithium ion battery, the control unit is configured to
(g) determine whether the storage battery is in a state where power storage amount stored by previous constant-voltage charging have been discharged for charging storage battery, and
(h) perform said (a) to (d) only when the control unit determines a discharged state.

7. A battery system comprising:
one or more storage batteries; and
the device for detecting remaining battery capacity according to any one of claim 1.

8. A method of detecting remaining battery capacity, comprising:
(a) detecting actual voltage of a storage battery with voltage detection means at start of charging storage battery;
(b) obtaining power storage amount corresponding to the actual voltage (hereinafter referred to as “power storage amount at start”) by using a look-up table representing a relationship between voltages and power storage amounts corresponding thereto;
(c) calculating power storage amount in the storage battery charged by implemented charging (hereinafter referred to as “calculated power storage amount”); and
(d) calculating total power storage amount of the charged storage battery, by adding the calculated power storage amount and the power storage amount at start.

9. The method of detecting remaining battery capacity according to claim 8, further comprising:
(e) monitoring relationship between voltage and power storage amount during charging, and updating power storage amount in the look-up table on the basis of the monitored data.

10. The method of detecting remaining battery capacity according to claim 9, when charge of storage battery is started except from a discharge end, the method further comprising in the step (e):
(e1) obtaining from the look-up table the power storage amount at start corresponding to the actual voltage of the storage battery,
(e2) calculating power storage amount stored by charging during one voltage section in the look-up table,
(e3) calculating total power storage amount, at the voltage, by adding the power storage amount at start and the power storage amount in said (e2), and
(e4) updating the power storage amount corresponding to the voltage with the calculated total power storage amount.

11. A program causing a computer to execute the processes of:
(a) referring to actual voltage of a storage battery, at start of charging storage battery, detected by voltage detection means;
(b) obtaining power storage amount corresponding to the actual voltage (hereinafter referred to as “power storage amount at start”) by using a look-up table representing a relationship between the voltages and the power storage amounts corresponding thereto;
(c) calculating power storage amount stored in the storage battery charged by implemented charging (hereinafter referred to as “calculated power storage amount”); and
(d) calculating total power storage amount of the charged storage battery, by adding the calculated power storage amount and the power storage amount at start.

12. The program according to claim 11, further causing the computer to execute a process of
(e) monitoring relationship between voltage and power storage amount during charging, and updating power storage amount in the look-up table on the basis of the monitored data.

13. The program according to claim 12, when charge of storage battery is started except from a discharge end, the program causing a computer to further execute in the step (e) the processes of:
(e1) obtaining from the look-up table the power storage amount at start corresponding to the actual voltage of the storage battery,
(e2) calculating a power storage amount stored by charging during one voltage section in the look-up table,
(e3) calculating total power storage amount, at the voltage, by adding the power storage amount at start and the power storage amount in said (e2), and
(e4) updating the power storage amount corresponding to the voltage with said total power storage amount.
